(19) United States
(12) Patent Application Publication
(10) Pub. No.: US 2026/0369342 A1
(43) Pub. Date: Nov. 19, 2026

(54) METHOD AND SYSTEM FOR TRIMMING MINIMUM RETENTION VOLTAGE FOR SRAM

(71) Applicant: Ambiq Micro, Inc, Austin, TX (US)

(72) Inventors: Dane Gentry, Austin, TX (US); Tony Malakkaran, Austin, TX (US); Edan Chen, Austin, TX (US); Bob Tseng, Austin, TX (US); Jamie Happ, Austin, TX (US)

(21) Appl. No.: 19/679,383

(22) Filed: May 15, 2026

Related U.S. Application Data
(60) Provisional application No. 63/807,386, filed on May 16, 2025.

(51) Int. Cl. G11C 29/56

(52) U.S. Cl. CPC G11C 29/56016; G11C 29/56004

(57) ABSTRACT

A system and method to determine minimum retention voltage for a static random access memory SRAM) is disclosed. The system includes a voltage output circuit coupled to an SRAM. A controller is coupled to a variable voltage output circuit and the SRAM. A test pattern is written to the SRAM and the voltage output is set to supply a current retention voltage level reduced by a predetermined increment to the SRAM. The controller reads the test pattern from the static random access memory and compares the written test pattern to the read test pattern. The controller determines whether the written test pattern matches the read test pattern and on a match, repeats the write, set, supply, read and compare operations. The controller outputs the current retention voltage as a specific retention voltage value for the SRAM if a match is not determined.

### PRIORITY CLAIM

The present disclosure claims priority to and the benefit of U.S. Provisional Serial No. 63/807,386 filed May 16, 2025. The contents of that application are hereby incorporated by reference in their entirety.

### TECHNICAL FIELD

The present invention relates generally to operation of a static random access memory (SRAM). More specifically, a system and method to trim a minimum data retention voltage for operating a SRAM are disclosed.

### BACKGROUND

In recent years, due to the growth of portable electronics, there has been a push to decrease the power used by microcontrollers (or “MCU”), microprocessors, application processors, digital signal processors (DSPs), neural processing units (NPUs), and other circuits used in portable electronic appliances. With lower power requirements, effective electronics operation time can be extended, or alternatively, smaller batteries can be used. Commonly, the power consumption of a microcontroller and associated circuits may be reduced by using a lower supply voltage, or by reducing the amount of internal capacitance being charged and discharged during the operation of the circuit.

One method for reducing microcontroller power relies on hardware or software-based power mode switching. Power modes can be selected for microcontroller components or resources based on operating state, operating conditions, and/or sleep cycle characteristics and other factors to configure low power modes for selected microcontroller components at the time the processor enters a low power or sleep state. In some systems, a set of predefined low power configurations can be used, while more sophisticated systems can dynamically select low power configurations to maximize power savings while still meeting system latency requirements.

It is common practice to run SRAM at a high voltage when reading and writing to ensure robust operation but to “droop” the voltage to a lower value (i.e., a retention voltage) during extended idle periods to enable lower leakage levels. Minimum power is generally achieved when the retention voltage is in the near-threshold or sub-threshold region. However, operating a SRAM below extremely low voltages (e.g., 0.2V or 0.3V) can result in failures so voltage at a critical retention voltage value must be maintained to ensure the SRAM will remain operational.

One area of power savings may be minimizing the retention voltage for the SRAM. As explained above, retention voltage is the minimum voltage that allows the SRAM to retain data. However, such voltage may differ from each SRAM module due to manufacturing variations. Currently, a single voltage source is used for all SRAM on a chip or device. The retention voltage for all SRAM modules must be set at a level to account for the largest possible retention voltage in all the modules. This is inefficient and requires additional power to retain data for all of the SRAM modules that may require a voltage less than the set retention level.

Thus, there is a need for a system and method to determine specific minimal retention voltages for individual SRAM modules. There is a need for a system and method to set minimal retention voltages for SRAM modules that result in power savings for a computer system on chip. There is also a need for a routine that determines minimal retention voltages for operating SRAM modules.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure a system to determine minimum retention voltage for a static random access memory is disclosed. The system includes a voltage output circuit coupled to a static random access memory. A controller is coupled to voltage output circuit and the static random access memory. The controller is operable to write a test pattern to the static random access memory. The controller is operable to set the voltage output circuit to supply a current retention voltage level adjusted by a predetermined increment to power the static random access memory. The current retention voltage level is adjusted by a predetermined increment is supplied to the static random access memory. The test pattern from the static random access memory is read and the written test pattern is compared to the read test pattern. The controller is operable to determine whether the written test pattern matches the read test pattern and on a match, repeat the write, set, supply, read and compare operations. The controller outputs the current retention voltage as a specific retention voltage value for the static random access memory if a match is not determined.

A further implementation of the example is where the test pattern is one of a plurality of test patterns. Another implementation is where the plurality of test patterns include at least one of all zeros, all ones, or alternating ones and zeros. Another implementation is where the controller is operable to add a margin value to the specific retention voltage. Another implementation is where the controller is operable to perform the read, compare and determine operations for supplying the specific retention voltage with the added margin value to a plurality of test patterns. Another implementation is where the adjustment reduces the current retention voltage level. Another implementation is where the current retention voltage is stored in a voltage regulator to output the current retention voltage to the SRAM. Another implementation is where the SRAM is integrated in a system on chip. Another implementation is where the minimum retention voltage is applied to another type of memory.

Another disclosed aspect is a method to determine a minimum retention voltage for a static random access memory. A test pattern is written to the static random access memory. A current retention voltage level adjusted by a predetermined increment is set to power the static random access memory. The current retention voltage level adjusted by the predetermined increment is supplied to the static random access memory. The test pattern is read from the static random access memory. The written test pattern is compared to the read test pattern. It is determined whether the written test pattern matches the read test pattern and on a match, the writing, setting, supplying, reading and comparing steps are repeated. The current retention voltage is output as a specific retention voltage value for the static random access memory if a match is not determined.

A further implementation of the example method is where the test pattern is one of a plurality of test patterns. Another implementation is where the plurality of test patterns include at least one of all zeros, all ones, or alternating ones and zeros. Another implementation is where the example method includes adding a margin value to the specific retention voltage. Another implementation is where the example method includes performing the read, compare and determine operations for supplying the specific retention voltage with the added margin value to a plurality of test patterns. Another implementation is where the adjustment reduces the current retention voltage level. Another implementation is where the example method includes storing the current retention voltage in a voltage regulator to output the current retention voltage to the SRAM. Another implementation is where the SRAM is integrated in a system on chip.

Another disclosed aspect is a system on chip that includes a static random access memory being powered at a specific retention voltage in a deep sleep mode. The system on chip includes a voltage output circuit supplying the specific retention voltage to the static random access memory. The specific retention voltage is determined by writing a test pattern to the static random access memory. A current retention voltage level adjusted by a predetermined increment is supplied to power the static random access memory. The current retention voltage level adjusted by the predetermined increment is supplied to the static random access memory. The test pattern is read from the static random access memory. The written test pattern is compared to the read test pattern. It is determined whether the written test pattern matches the read test pattern and on a match, the writing, setting, reading and comparing steps are repeated. The current retention voltage is set as the specific retention voltage value if a match is not determined.

A further implementation of the example system on chip is where the voltage output circuit is a buck converter. Another implementation is where the example system on chip includes another memory, where the another memory is powered at the specific retention voltage.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure will be better understood from the following description of exemplary embodiments together with reference to the accompanying drawings, in which:

FIG. 1 is a diagram of a system on chip in an energy efficient device requiring near threshold voltages for various components;

FIG. 2 is a block diagram of the example system on chip in FIG. 1;

FIG. 3 is a block diagram of an example SRAM and components that allow the fine tuning of the retention voltage;

FIG. 4A is a general flow diagram of the example method to determine a minimum retention voltage for an SRAM on a system on chip;

FIG. 4B is a detailed flow diagram of the general steps of the diagram in FIG. 4A;

FIG. 5A-5C are a flow diagram of an example routine to determine a minimum retention voltage for a SRAM; and

FIG. 6 is an example test system for determining retention voltage sources for a SRAM on a system on chip.

The present disclosure is susceptible to various modifications and alternative forms. Some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements, and limitations that are disclosed, for example, in the Abstract, Summary, and Detailed Description sections, but not explicitly set forth in the claims, should not be incorporated into the claims, singly, or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

The present disclosure is directed toward a method to determine a minimum retention voltage for a static random access memory (SRAM) block. The SRAM is tested incrementally by storing a test pattern at a test retention voltage at one of the SRAM addresses and applying a lower retention voltage. The SRAM is then powered up and the test pattern is read from the SRAM. After each successful test, the retention voltage is adjusted by a lower incremental value. The test is then run with applying the lowered retention voltage. This is repeated until the SRAM fails to accurately store the test pattern. When this occurs, a minimal retention voltage is determined for the SRAM module block from the previously tested retention voltage level. The minimal retention voltage is then applied to operate the SRAM. The example method may be used to output a trim value to set the retention voltage for a specific SRAM installed in a device such as a system on chip, thus conserving power required to operate the SRAM.

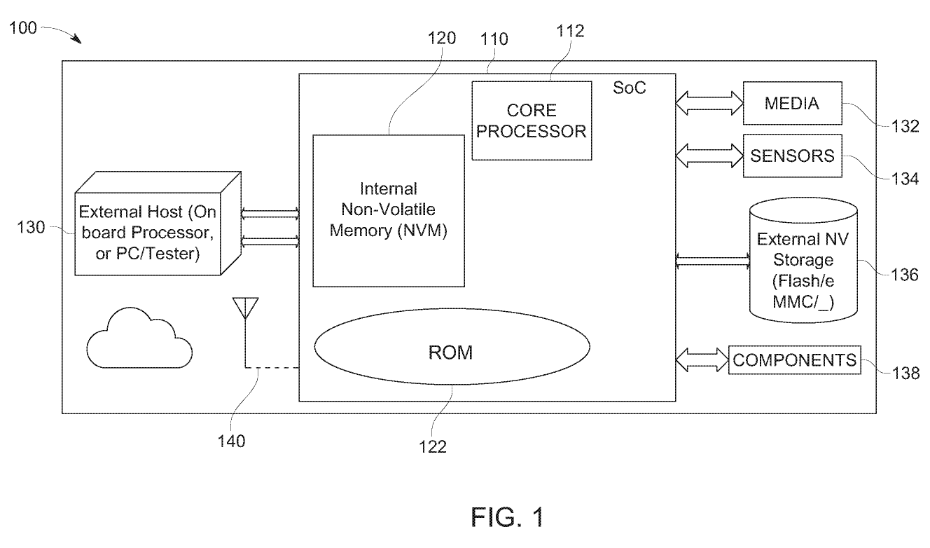

FIG. 1 shows a block diagram of a device 100 with a system on chip 110. The system on chip 110 includes a core processor 112 and non-volatile memory 120 that is a magneto-resistive RAM (MRAM). The system on chip 110 also includes permanent memories such as a read only secure boot read only memory (ROM) 122. In this example, the system on chip 110 is installed in the device 100 and the core processor 112 executes applications generally stored in the non-volatile memory 120 to operate the device 100 to perform different functions.

The device 110 may include an external host processor 130 that controls the functions of the system on chip 110, which may be connected via wired interfaces such as UART, SPI, or I2C interfaces. The system on chip 110 controls and accesses a set of components on the device 100 that may include media devices 132 such as a display or an audio output, sensors 134, a non-volatile (NV) memory device 136 such as MSPI Flash or eMMC, or other components 138. As will be explained the NV memory device 136 serves as an alternate storage device for storing a recovery image. The host processor 122 could be coupled to a wireless interface 140 such as Bluetooth or Wi-Fi that allows communication with external components to the device 100. A battery provides power to the components of the device 100 including the system on chip 110.

Although not all of the electronic components illustrated in FIG. 1 may be operable in the sub-threshold or near-threshold domains in any particular embodiment, some, at least, may be advantageously adapted to do so, with concomitant reductions in system power dissipation.

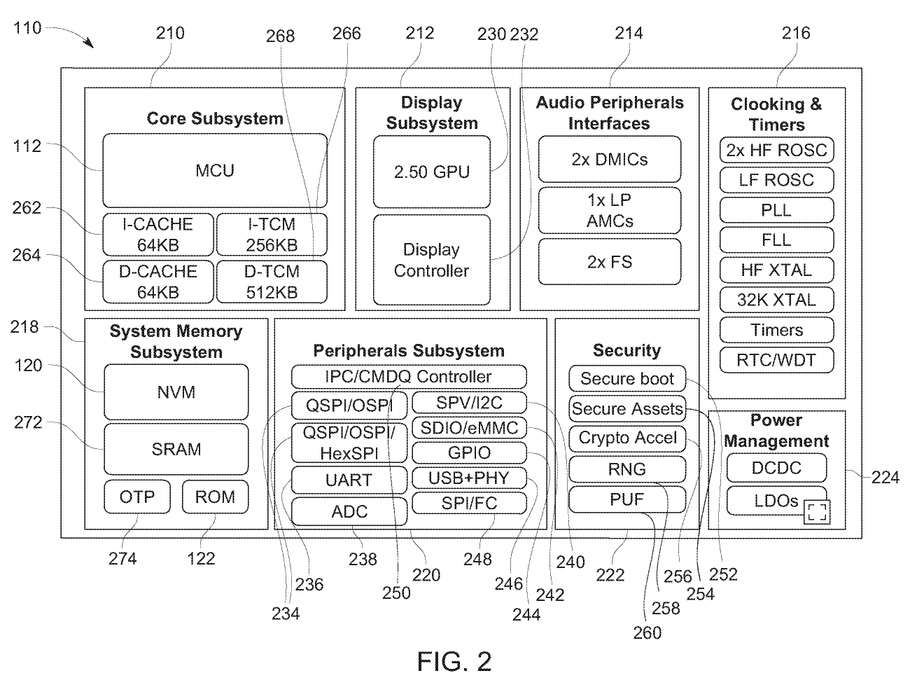

FIG. 2 shows a block diagram of the system on chip 110 in FIG. 1. The system on chip 110 includes a core subsystem 210, a display subsystem 212, an audio peripherals subsystem 214, a clock and timers subsystem 216, a memory subsystem 218, a peripheral subsystem 220, a security subsystem 222, and a power management subsystem 224. The display subsystem 212 includes a graphic processor 230 and a display controller 232 to drive displays on the device 100. The audio peripherals subsystem 214 includes different audio peripheral interfaces for driving audio components on the device 100. The clock subsystem 216 includes timers and clocks for the system on chip 110.

The peripheral subsystem 220 includes different interfaces such as QSPI/OSPI/HexSPI interfaces 234, UART interfaces 236, analog to digital converters 238, SP/I2C master interfaces 240, SDIO (Secure Digital Input Output)/MMC (Multi-Media card) interfaces 242, a set of general purpose input/output (GPIO) pins 244, a USB interface 246, and a SPI slave interface 248. The peripheral interfaces are managed by a peripheral controller 250 that manages inter process communication (IPC) and a command queue (CMDQ). The security subsystem 222 includes a secure boot 252, security assets 254, a crypto accelerator 256, a random number generator (RNG) 258 and a physical unclonable function (PUF) 260. The power management subsystem 224 includes power sources such as low drop out (LDO) and DC power regulator supply sources.

The core subsystem 210 includes the core processor 112 that may be any suitable processor, microcontroller, and the like. In this example, the core processor 112 is an ARM Cortex MCU, but any suitable programmable controller or processor may be used. The core subsystem 210 includes an instruction cache 262 and a data cache 264. The core subsystem 210 includes an instruction tightly controlled memory (TCM) 266 and a data TCM 268. The memory subsystem 218 includes synchronous static random access memory (SSRAM) 272, a one-time programmable (OTP) device 274, and the read only memory (ROM) 122. In this example, the OTP device 274 is an e-fuse. The OTP device 274 stores data such as trim values that may written during production testing and are read by the core processor 112 for tuning components such as a voltage regulator that supplies voltage to the SSRAM 272. The memory subsystem 218 also includes the non-volatile memory 120, which is MRAM in this example.

The power management subsystem 224 includes one or more voltage converters that provide voltage to both digital modules such as the core subsystem 210 and analog modules such as the clocking and timers subsystem 216 and analog to digital converters (“ADC”) in the peripheral subsystem 220, and the like. The power management subsystem 224 includes reference voltage generators and reference current generators. The reference voltage generator and reference current generator are each common modules for supplying a stable reference signal to analog modules on the chip 110. The reference voltage generator is sometimes used to derive the output reference current provided by reference current generator.

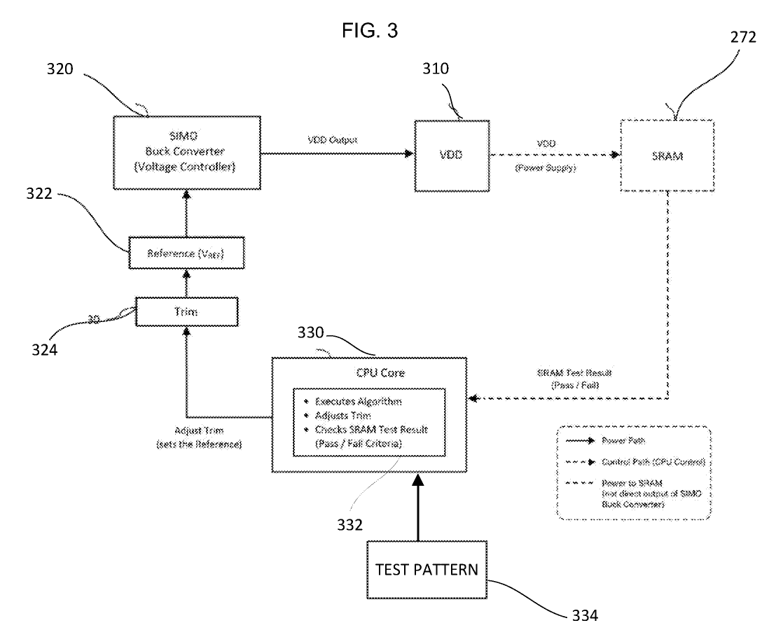

FIG. 3 shows a block diagram of components that provide the example SRAM 272 in FIG. 2 with a specific minimum retention voltage that may be determined via the example method. In this example, the SRAM 272 is a series of 32 bit registers. A retention voltage (VDDS) source 310 provides a minimum retention voltage to the SRAM 272 to retain stored data when the SRAM is in deep sleep. The retention voltage source 310 is generated by a power circuit such as a SIMO buck converter 320. The output voltage of the buck converter 320 is controlled by a reference voltage controller 322. In this example, the retention voltage output (VDDS) 310 from the buck converter 320 is set to a tuned value specific to the SRAM 272 after the example retention voltage determination process. The tuned value is produced by setting a trim value 324 for the reference voltage controller 322.

In this example, the process is executed by a CPU core 330 to determine the trim value 324. The CPU core 330 thus executes a test routine 332 that executes an algorithm based on testing the SRAM 272. The CPU core 330 has access to test patterns stored on a memory device 334. Based on the test, the test routine 332 adjusts the trim value and checks the test of the SRAM 272. The minimum retention voltage for other memory and peripherals for a second voltage output (VDDF) may also be set by the trim value 324 to the buck converter 320. Of course other controllable voltage generators may be used such as a voltage regulator to supply the retention voltage.

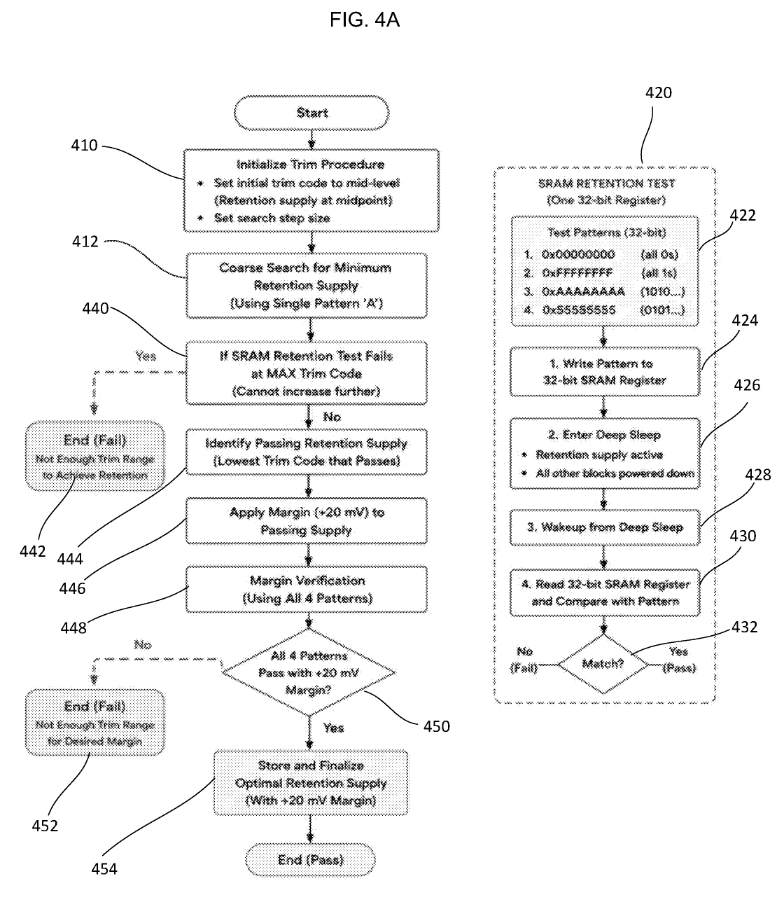

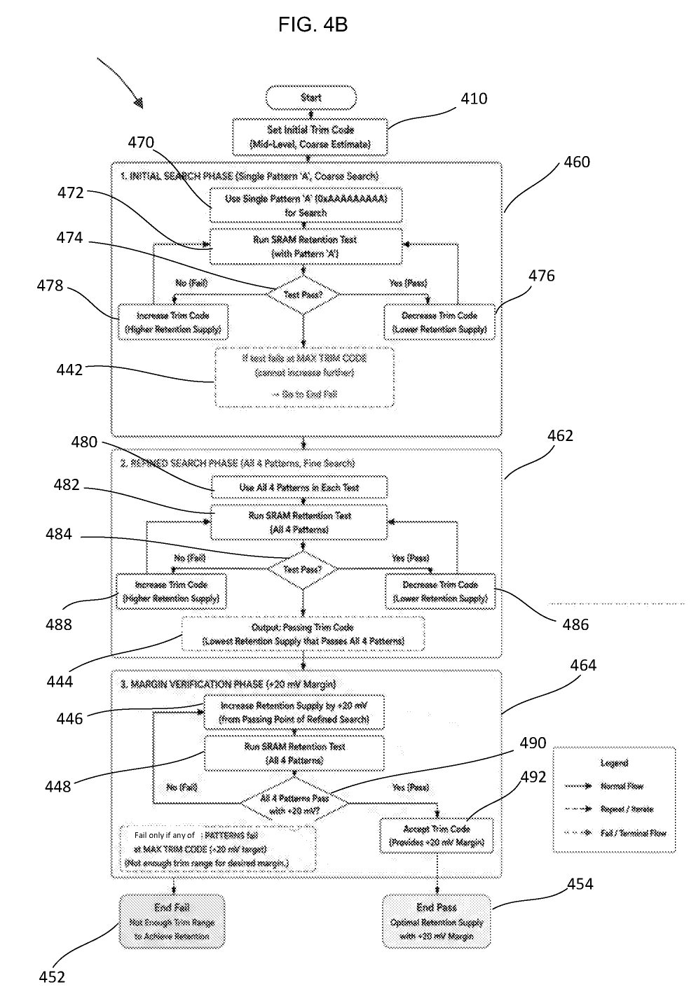

FIG. 4A is a high level overview flow diagram of the test routine executed by the CPU core 330 in FIG. 3. The routine first initializes the trim procedure (410). In this example, the trim values are equated to a range of codes that correlate to different voltage values for the retention voltage. In this example, the higher codes correlate with higher voltage levels, while the lower code values correlate with lower voltage levels. In the initialization step, the routine sets the initial trim code to a mid-level code that correlates to the midpoint of the retention voltage range. The search step size is also set for incrementing the retention voltage in the testing process.

The routine first conducts a coarse search for the minimum retention voltage using a single test pattern to conduct the testing (412). The coarse search includes a test routine 420. In this example the test routine 420 is designed for testing each of the 32 bit registers of the SRAM. A set of 32 bit test patterns (422) is stored in the SRAM for use in the test. In this example, there are four test patterns, including a first test pattern of all 0s (Hex 0x00000000), a second test pattern of all 1s (Hex 0xFFFFFFFF), a third test pattern of alternating 1s and 0s, starting with a 1 (Hex 0xAAAAAAAA), and a fourth test pattern with alternating 0s and 1s, starting with a 0 (Hex 0x55555555). The test routine 420 first writes a pattern selected from the four patterns to each of the 32-bit registers in the SRAM (424). The routine then enters a deep sleep mode (426) where the tested retention voltage is active, but other including the SRAM are powered down in order to minimize power usage in the deep sleep mode. After a suitable time, the SRAM registers are woken from the deep sleep by powering the other blocks to allow a read or write operation (428). The SRAM register are then read and compared with the pattern (430). If the read pattern matches the test pattern (432), the test passes and the retention voltage is sufficient to power the SRAM in the deep sleep mode. If the read pattern does not match the test pattern, the test is a failure.

After performing the coarse search for the minimum retention supply (412), the routine determines whether the test (420) fails at the maximum trim code that cannot be increased (440). If the test fails at the maximum trim voltage level, the routine outputs a fail and ends (442). This indicates that there is not enough trim range to achieve a suitable retention voltage for the SRAM.

If the test succeeds at the maximum trim code, the routine identifies the lowest trim code that passes the retention test (444). Once the lowest retention voltage is identified, the routine applies a margin to the passing level such as 20mV (446). The routine then performs verification of the retention voltage with the margin by testing the SRAM with all four test patterns (448). The routine determines whether the SRAM is successful with all four test patterns (450). If there is a failure on any of the test patterns, the routine outputs a fail because there is not enough trim range to increase the +20mv margin even with max trim code (452). If the retention voltage with the margin results in successful testing of the four test patterns, the retention voltage is stored as the trim value for operation of the SRAM (454).

FIG. 4B is a detailed flow diagram of some of the steps of FIG. 4A. The routine has an initial search phase 460, a refined search phase 462, and a margin verification phase 464. In this example, the initial search phase 460 includes steps 412, 440, and 442 of FIG. 4A. Specifically, a single pattern is selected such as the first search pattern of all zeros (470). The SRAM retention test in step 420 in FIG. 4B is run with the initial retention voltage (472). The routine determines whether the test is successful (474). If the test is successful, the trim code is lowered, resulting in a lower retention voltage (476). The test (472) is then run at the lower retention voltage. If the test (472) is unsuccessful, the trim code is increased to obtain a higher retention voltage (478). The test (472) is then run using the higher retention voltage. If the test fails at the highest retention voltage (code), the routine ends with a fail (442).

The refined search phase 462 includes step 444 of FIG. 4A. Specifically, all available patterns such as all four search patterns 422 in FIG. 4A are tested using the retention voltage (480). The SRAM retention test in step 420 in FIG. 4B is run on all the patterns (482). The routine determines whether the test is successful for all the patterns (484). If the test is successful for all the patterns, the trim code is lowered, resulting in a lower retention voltage (486). The test (482) is then run on all the patterns at the lower retention voltage. If the test is unsuccessful, the trim code is increased to obtain a higher retention voltage (488). The test (482) is then run on all patterns using the higher retention voltage. The routine determines the lowest retention voltage that allows all patterns to pass (444).

The margin verification phase 464 includes steps 446, 448, 450, and 442 of FIG. 4A. The retention voltage is increased by a selected increment such as 20 mV (446). The retention test is then run for all four pattens on the increased retention voltage (448). The routine determines whether all four patterns were successfully retained (490). If all four patterns were successfully retained, the routine accepts the trim code with the margin (492) and the routine ends (454). If any of tests of the four patterns fail (490), the routine loops back to increase the retention voltage by increasing the margin by an additional increment (446). The routine fails if any of the tests of the four patterns fail at the maximum trim code (452).

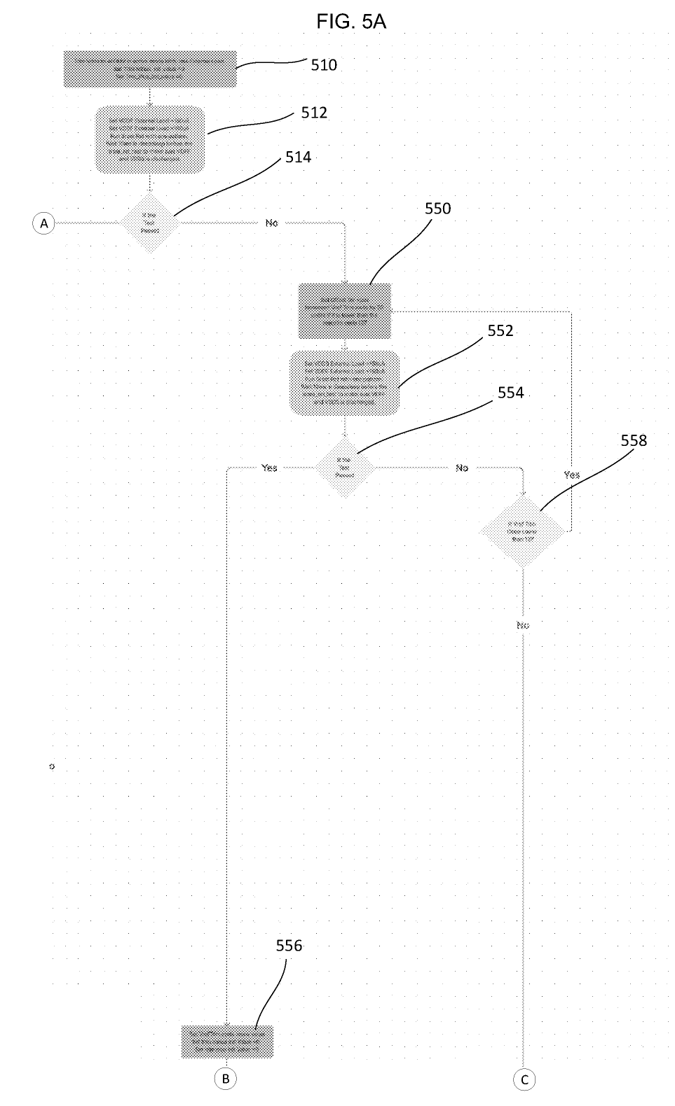

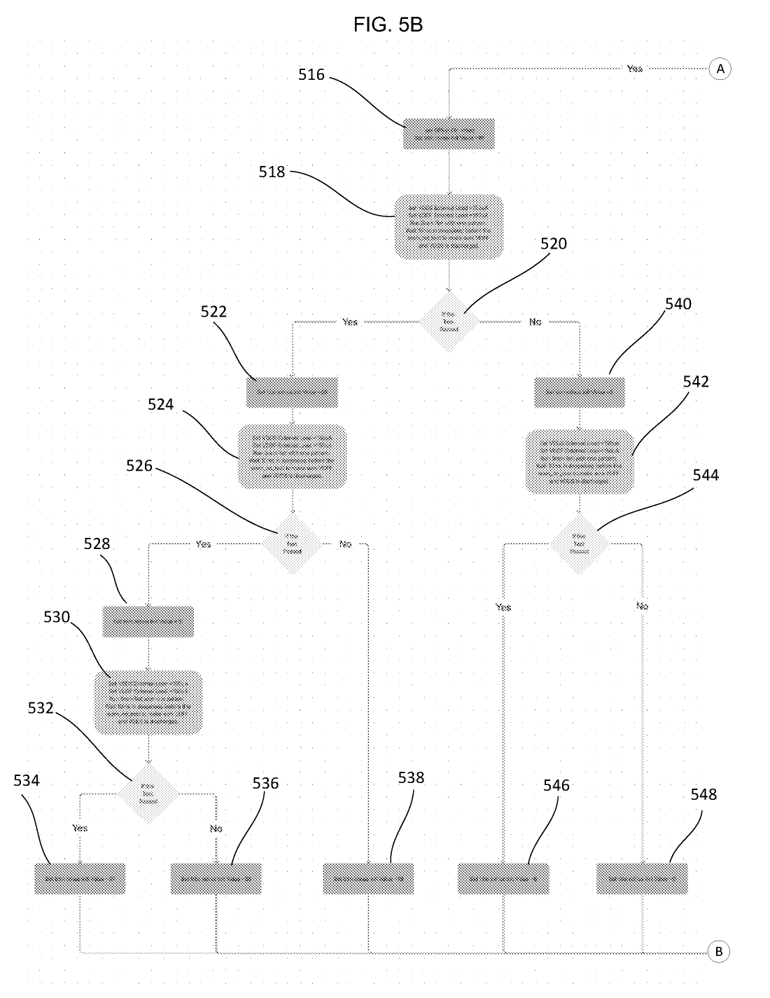

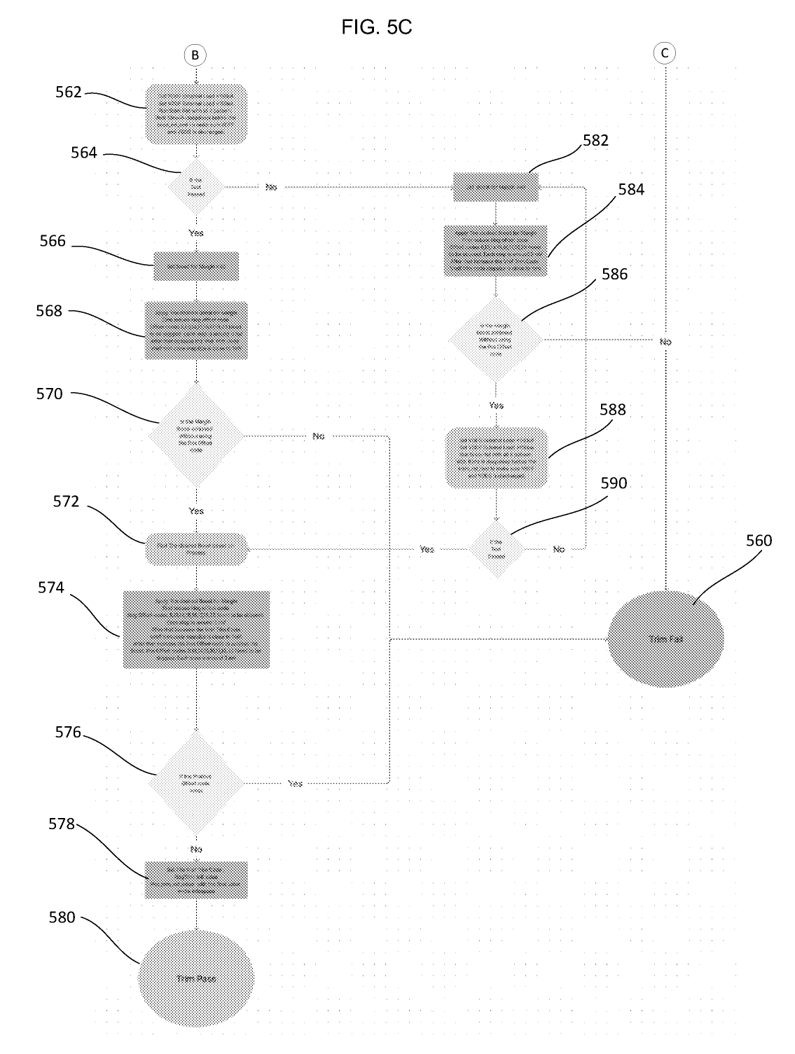

FIGS. 5A-5C are a flow diagram of an executable routine incorporating the example method to determine a specific retention voltage for a SRAM module such as the SRAM 272 in FIG. 3. The flow diagrams in FIGS. 5A-5C are representative of example machine readable instructions for routines to determine a minimum retention voltage for an SRAM module. In this example, the machine readable instructions comprise an algorithm for execution by: (a) a processor; (b) a controller; and/or (c) one or more other suitable processing device(s). The algorithm may be embodied in software stored on tangible media such as flash memory, CD-ROM, floppy disk, hard drive, digital video (versatile) disk (DVD), or other memory devices. However, persons of ordinary skill in the art will readily appreciate that the entire algorithm and/or parts thereof can alternatively be executed by a device other than a processor and/or embodied in firmware or dedicated hardware in a well-known manner (e.g., it may be implemented by an application specific integrated circuit [ASIC], a programmable logic device [PLD], a field programmable logic device [FPLD], a field programmable gate array [FPGA], discrete logic, etc.). For example, any or all of the components of the interfaces can be implemented by software, hardware, and/or firmware. Also, some or all of the machine readable instructions represented by the flowcharts may be implemented manually. Further, although the example algorithm is described with reference to the flowcharts illustrated in FIGS. 5A-5C, persons of ordinary skill in the art will readily appreciate that many other methods of implementing the example machine readable instructions may alternatively be used. For example, the order of execution of the blocks may be changed, and/or some of the blocks described may be changed, eliminated, or combined.

The routine sets a reference voltage code (Vref trim code) that is the code for the initial minimum retention voltage used for testing the SRAM. The example routine stores different variables including a trim minus value (Trim Minus_initi_value), which is the trim value to be tested after a decrease in the voltage, a trim plus value (Trim Plus_initi_value), which is the trim value to be tested after an increase in voltage, and a boost for margin, which is the safety margin added to the minimum retention voltage. The routine also sets the value for the external loads when the SRAM is in a deep sleep mode requiring a retention voltage to store data. The routine includes a Boolean variable for whether the offset is positive or negative (Offset Dir).

The routine is provided a set of codes that reflect different voltage levels. In this example, the code values range between 0 and 127, which correspond to a range of minimum retention voltages to be tested. The codes are determined by calibrating the range of minimum retention voltages with each of the codes. The codes are used for reducing the tested retention voltage trim values. In this example there are four code increments that range 0-31 from a largest increment (31 codes), a larger increment (26 codes), a smaller increment (19 codes), and a smallest increment (6 codes). These increments are selected to efficiently determine the minimal retention voltage in the routine by subtracting one of the selected increments. Other increments of different value codes may be used.

The initial working subsystem voltage (VDDS) is trimmed to a given initial value at a specific current load while the components are in an active mode (510). In this example, the initial value is determined from the design specification such as 480mV with a 1 mA external load. The variables of trim plus initial value and trim minus initial value are set to zero. The external load for the SRAM retention voltage (VDDS) and peripheral retention voltage (VDDF) for a deep sleep mode are set at a certain level such as 150 µA and an initial test pattern is stored in the SRAM under test (512). The initial retention voltage level is then applied to the SRAM to be tested. A certain time delay such as 10ms occurs before the SRAM is read at the initial VDDS voltage level to ensure the VDDS and VDDF voltages are discharged. The routine then determines if the SRAM successfully stored the test pattern (514).

If the test is successful (514), the incremental direction variable is set to negative to indicate the trim value should be decreased, and the trim minus initial value for the retention voltage of the SRAM is set to a middle value code (e.g., 19) (516) in FIG. 5B. The test process is run again with reduced trim value determined by subtracting the code value from the initial trim value and the previous load parameters and wait time for storing the test pattern in the SRAM (518). The routine then determines if the SRAM successfully stored the test pattern (520). If the SRAM passes the test (420), the trim minus initial value is set to a larger code (e.g. 26) (522). The SRAM is then tested again with the new trim value determined by the previous trim value used for the test (518) minus the trim minus code with the previous load parameters and wait time for storing the test pattern in the SRAM (524). The routine determines whether the test was successful (526).

If the test was successful (526), the trim minus initial value is set to the largest code value (e.g., 31) (428). The test is then run with the current values and times with the new trim value determined by subtracting the trim minus value from the previous trim value tested (524) with the previous load parameters and wait time for storing the test pattern in the SRAM (530). The routine then determines whether the test was successful for the new trim value (532).

If the test was successful (532), the routine sets the trim value for the retention voltage to the largest code value (e.g. 31) (534). If the test was unsuccessful (532), the routine sets the trim minus initial value for the retention voltage to the second largest code value (e.g., 26) (536). If the test using the trim value in (524) is unsuccessful (526), the routine sets the trim minus initial value for the retention voltage to the smaller value (e.g., 19) (538).

If the test pattern was not successfully stored based on the trim value determined by subtracting the smaller code value (e.g., 19) (520), the routine will set the trim minus initial value to the smallest code value (e.g., 6) (540). The routine will conduct the test with a new trim value that subtracts the smallest code value from the previous trim value with the previous load parameters and wait time for storing the test pattern in the SRAM (542). The routine will determine whether the test was successful (544). If the test with the trim value (542) was successful, the routine will set the trim minus initial value to the smallest value (e.g., 6) (546). If the test (542) was unsuccessful, the routine will set the trim minus initial value to 0 (548).

Returning to FIG. 5A, if the test with the initial trim value (514) is unsuccessful, the offset direction variable is set to positive thus instructing the routine to increase the trim voltages by various increments to determine the minimal retention voltage (550). The trim code is incremented by 20 codes if the retention voltage trim code is lower than the maxtrim code (e.g., 127) (550). The external loads of the VDDS and VDDF are set at a certain current level such as 150µA for deep sleep mode and an initial test pattern is stored in the SRAM module. The retention voltage determined by the trim is then applied to the SRAM and the SRAM is read to determine if the test pattern was stored successfully (552).

The routine then determines if the test is successful at the positively offset trim level (554). If the test is successful (554), the routine sets the trim plus value variable to the previous reference voltage value incremented by 20 codes and the trim plus and minus initial values are set to zero (556). If the test is unsuccessful (554), the routine determines whether the trim reference voltage code is lower than the max trim code (e.g., 127) (558). If the trim reference voltage code is lower than the max trim code, the routine loops back to increment the trim reference voltage code by 20 to arrive at a new trim reference voltage code (550). If the trim reference voltage code is not lower than the max trim code (558), the routine ends with a trim fail output (560).

After setting the trim minus initial value in steps 536, 538, 540, 546, or 548, the routine will set the previous load parameters and wait time for storing the test pattern in the SRAM (562). In this example, four test patterns will be applied to the SRAM. The routine then determines whether the test (562) is successful for all of the four test patterns (564). If the test is successful (464), the boost margin is set to a smaller value (20mV) (566). The set boost margin is applied by incrementing the trim minus init and vref trimcode (568). First, the trim minus init value is reduced, skipping some specific codes because of nonlinearities. The step size of each code in the minus initi is 3mV. If the boost margin is not achieved by reducing the trim minus init, the vref trim code is increased. The step size of teach trim code is 1mV. The routine then determines the desired boost value is achieved without using the positive offset code (570). If the desired boost is not achieved without using the positive offset code, the routine will output a trim fail (560). If the desired boost is achieved without using the positive offset code (570), the desired boost is then found based on a process of determining process corners for transistors on the SoC since the margin required for each corner is slightly different (572). The desired boost is then applied (574). This includes reducing the negative offset code while skipping certain codes. After the negative offset code is reduced, the reference voltage trim code is increased. The positive offset code is increased to achieve the desired boost (574). Certain positive offset codes are skipped because of nonlinearities. The routine then determines whether the positive offset code is greater than a maximum value (576). If the positive offset code is greater than the maximum value, the routine will output a trim fail (560). If the positive offset code is less than the maximum value, the routine will set the voltage reference trim code value, the positive initial value, and the negative initial value with the values found in the process margin boost step (574) in the info space. The routine will then end with a trim pass (580).

If the test (564) is unsuccessful, the routine will set the boost for margin at 40 (582). The routine will then apply the desired boost for margin (584). The negative offset code will be reduced. Certain negative offset codes will be skipped. The trim code for the reference voltage is increased. The routine then determines whether the margin boost is achieved without using the positive offset code. If the margin boost is not achieved without using the positive offset code, the routine will output a trim fail (560). If the margin boost is achieved without using the positive offset code, a test with multiple test patterns at set external loads and time in deep sleep is applied (588). If the test is successful (588), the routine will find the desired boost based on the process (572). If the test is unsuccessful (588), the routine will loop back and set the boost margin to 540 (582).

In an example for executing the routine, the VDDS is trimmed to a lower voltage of 480mV in active mode with an external load of 1mA for a SRAM in this example.

A SRAM retention test is used to test the SRAM module 272 at the initial values of the working voltage for retaining data. In this example test, a maximum retention voltage is applied that is sufficient so all memory cells in all SSRAM and all TCM retain stored data values. The test is conducted to determine the minimum VDDS voltage in DeepSleep mode for such memory devices. In this example, a 150uA external load is assumed with the VDDS in the DeepSleep mode. In this example, the VDDS voltage was tuned to the lowest possible level during a production test at 25C. This tuning characterizes the memory retention voltage across temperature and tuning of the VDDS piecewise linear (PWL) hardware temperature compensation settings of the buck converter that serves as the VDDS source. This provided a slope adjustable voltage over a temperature increase from - 40C to 25C.

The VDDS voltage in DeepSleep mode is reduced by some increment until the SRAM retention test fails. In this example, four patterns are used in the example SRAM retention tests. These patterns are written into the SRAM and the test retention voltage is applied. The patterns are then read back from the SRAM. The SRAM passes the retention if the read pattern matches the test pattern. In this example, Pattern 1 is generally used for the tests in the coarse adjustment in FIG. 4A-4B. Of course other types of patterns and different numbers of patterns may be used.

In this example, the VDDS voltage in the DeepSleep mode is adjusted using a trim code. The trim code may include plus and minus initialization values for a buck converter. In an example Apollo 5 system the “tvrgsvref” trim code as well as the “simobuck_vdds_comptrim_minus_init_value” trim code and the “simobuck_vdds_comptrim_plus_init_value” trim code store the initialization values.

In this example, the determined VDDS voltage for retention is boosted by a certain value for a safety margin. In this example, the determined retention voltage is boosted 20mV (for margin) above the minimum passing voltage.

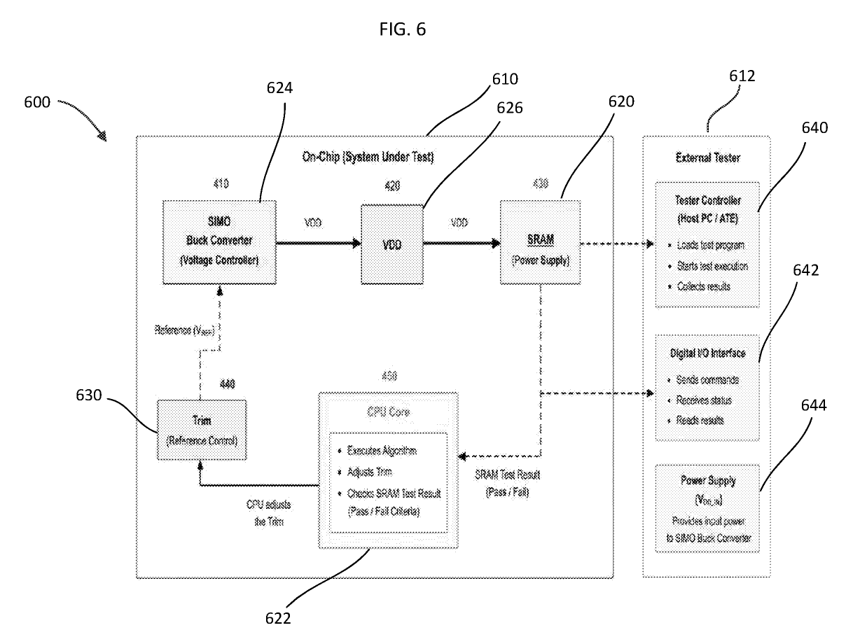

FIG. 6 shows an example testing system 600 that determines the trim values for retention voltages for a system on chip 610. The testing system 600 includes an external tester 612 to determine minimum retention voltage for a static random access memory (SRAM) 620 on the system on chip 610. The system on chip 610 includes a processor core 622 and a voltage output circuit such as a SIMO buck converter 624. The voltage output of the buck converter 624 is coupled to the SRAM 620 to serve as the retention voltage source (VDD) 626. The voltage output of the buck converter 624 is determined by a trim reference control circuit 630. The trim value for the reference control circuit 630 is set by the processor core 622.

The external tester 612 includes a tester controller 640, a digital input/output interface 642, and a power supply 644. The tester controller 640 in this example is a host computer/ Automated Test Equipment (ATE) such as the LTX-Credence D10 (Diamond 10). The tester controller 640 loads the test program, starts the test execution and collects the test results from the system on chip 610. The digital input/output interface 642 is coupled to the system on chip 610 to send commands and receive status signals and test results. In this example, the power supply 644 supplies power to the SIMO buck converter 624.

In this example, the processor core 622 is a controller that is coupled to the voltage output circuit in the form of the buck converter 624 and the SRAM 620. The processor core 622 executes the routine to write a test pattern to the SRAM 620. The routine sets the voltage output circuit via the trim to supply a current retention voltage level adjusted by a predetermined increment to the SRAM 620. The current retention voltage level is adjusted by a predetermined increment to be applied to the SRAM 620. The processor core 622 reads the test pattern from the SRAM 620 and compares the written test pattern to the read test pattern. The routine determines whether the written test pattern matches the read test pattern and on a match, repeats the write, set, supply, read and compare operations. The core processor 620 outputs the current retention voltage as a specific retention voltage value for the SRAM 620 if a match is not determined.

While various embodiments of the present invention have been described above, it should be understood that they have been presented by way of example only, and not limitation. Numerous changes to the disclosed embodiments can be made in accordance with the disclosure herein, without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations, and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

Each of these embodiments and obvious variations thereof is contemplated as falling within the spirit and scope of the claimed invention, which is set forth in the following claims.

What is claimed is:

1. A system to determine minimum retention voltage for a static random access memory, the system comprising:
a voltage output circuit coupled to a static random access memory;
a controller coupled to voltage output circuit and the static random access memory, the controller operable to:
write a test pattern to the static random access memory;
set the voltage output circuit to supply a current retention voltage level adjusted by a predetermined increment to power the static random access memory;
supply the current retention voltage level adjusted by the predetermined increment to the static random access memory;
read the test pattern from the static random access memory;
compare the written test pattern to the read test pattern;
determine whether the written test pattern matches the read test pattern and on a match, repeat the write, set, supply, read and compare operations; and
output the current retention voltage as a specific retention voltage value for the static random access memory if a match is not determined.

2. The system of claim 1, wherein the test pattern is one of a plurality of test patterns.

3. The system of claim 2, wherein the plurality of test patterns include at least one of all zeros, all ones, or alternating ones and zeros.

4. The system of claim 1, wherein the controller is operable to add a margin value to the specific retention voltage.

5. The system of claim 4, wherein the controller is operable to perform the read, compare and determine operations for supplying the specific retention voltage with the added margin value to a plurality of test patterns.

6. The system of claim 1, wherein the adjustment reduces the current retention voltage level.

7. The system of claim 1, wherein the current retention voltage is stored in a voltage regulator to output the current retention voltage to the SRAM.

8. The system of claim 1, wherein the SRAM is integrated in a system on chip.

9. The system of claim 1, wherein the minimum retention voltage is applied to another type of memory.

10. A method to determine a minimum retention voltage for a static random access memory, the method comprising:
writing a test pattern to the static random access memory;
setting a current retention voltage level adjusted by a predetermined increment to power the static random access memory;
supplying the current retention voltage level adjusted by the predetermined increment to the static random access memory;
reading the test pattern from the static random access memory;
comparing the written test pattern to the read test pattern;
determining whether the written test pattern matches the read test pattern and on a match, repeating the writing, setting, supplying, reading and comparing steps; and
outputting the current retention voltage as a specific retention voltage value for the static random access memory if a match is not determined.

11. The method of claim 10, wherein the test pattern is one of a plurality of test patterns.

12. The method of claim 10, wherein the plurality of test patterns include at least one of all zeros, all ones, or alternating ones and zeros.

13. The method of claim 10, further comprising adding a margin value to the specific retention voltage.

14. The method of claim 13, further comprising performing the read, compare and determine operations for supplying the specific retention voltage with the added margin value to a plurality of test patterns.

15. The method of claim 10, wherein the adjustment reduces the current retention voltage level.

16. The method of claim 10, further comprising storing the current retention voltage in a voltage regulator to output the current retention voltage to the SRAM.

17. The method of claim 10, wherein the SRAM is integrated in a system on chip.

18. A system on chip comprising:
a static random access memory being powered at a specific retention voltage in a deep sleep mode; and
a voltage output circuit supplying the specific retention voltage to the static random access memory, wherein the specific retention voltage is determined by:
writing a test pattern to the static random access memory;
setting a current retention voltage level adjusted by a predetermined increment to power the static random access memory;
supplying the current retention voltage level adjusted by the predetermined increment to the static random access memory;
reading the test pattern from the static random access memory;
comparing the written test pattern to the read test pattern;
determining whether the written test pattern matches the read test pattern and on a match, repeating the writing, setting, reading and comparing steps; and
setting the current retention voltage as the specific retention voltage value if a match is not determined.

19. The system on chip of claim 18, wherein the voltage output circuit is a buck converter.

20. The system on chip of claim 18, further comprising another memory, wherein the another memory is powered at the specific retention voltage.
